(19) United States
(12) Patent Application Publication
(10) Pub. No.: US 2004/0152260 A1
(43) Pub. Date: Aug. 5, 2004

(54) Non-volatile memory cell with non-uniform surface floating gate and control gate

(76) Inventors: Peter Rabkin, Cupertino, CA (US); Hsingya Arthur Wang, San Jose, CA (US); Kai-Cheng Chou, San Jose, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(21) Appl. No.: 09/948,612

(22) Filed: Sep. 7, 2001

(51) Int. Cl. H01L 21/336

(52) U.S. Cl. 438/257

(57) ABSTRACT

The present invention provides non-volatile memory cell transistors that have increased control-to-floating gate coupling coefficients due to a non-uniform gate surface area. In memory cells of the present invention, the floating gate is formed with a non-flat, non-uniform surface, which significantly increases the surface area interface between the floating gate and the inter-gate dielectric as well as the surface area interface between the inter-gate dielectric and the control gate. As a result, the inter-gate capacitance and the gate coupling coefficient are significantly increased. A high gate coupling coefficient allows the creation of small sized high performance memory cells that have high program and erase efficiency and read speed and can function at lower operation voltages. Higher gate coupling ratio allows also lowering operation voltages of memory cell which simplifies flash chip design, especially for lower power supply voltages.

### BACKGROUND OF THE INVENTION

A prior art non-volatile memory cell structure is illustrated in FIGS. 1A-1B. FIG. 1A illustrates a cross section view of the prior art cell along a word line, and FIG. 1B illustrates a cross section of the prior art cell along a bit line of a memory device. Isolation regions 11A-11B are formed in a silicon substrate using well-known shallow trench isolation (STI) process steps. Oxidation is performed to form tunnel oxide region 15 in between STI regions 11A-11B. A first polysilicon layer 12 (Poly1) is deposited and patterned as shown in FIGS. 1A-1B. Polysilicon layer 12 forms the floating gates of the memory cells. An inter-polysilicon dielectric such as oxide-nitride-oxide (ONO) composite layer 13 is deposited on polysilicon layer 12 in memory array and removed in the peripheral regions of the flash chip.

Second polysilicon layer 14 (Poly2) is deposited on top of ONO composite layer 13, followed by the deposition of other gate stack layers such as tungsten silicide (WSi_{X}), or cobalt silicide, or other layers. ONO composite layer 13 insulates polysilicon layer 14 from polysilicon layer 12. A gate mask is used to define the memory cell control gate for polysilicon layer 14 (Poly2), and the peripheral transistor gates if polysilicon 14 is used for peripheral transistor gates. Subsequently, the gate stacks for the memory cells are formed using a self-aligned etch process.

An important parameter that determines the performance of the memory cells is the gate coupling coefficient. The gate coupling coefficient has a primary effect on the potential of the floating gate. A higher gate coupling coefficient brings the potential of the floating gate closer to that of the control gate for any given potential on the control gate of the memory cell. The closer the potential on the floating gate to that of the control gate for a given control gate bias, the better the performance of the memory cell, including higher program and erase efficiency and read current. Higher gate coupling ratio allows also lowering operation voltages of memory cells simplifying flash chip design, especially for lower power supply voltages.

The upper surface of polysilicon layer 12 (Poly1) is relatively smooth and uniform. A capacitor (referred to as the inter-polysilicon capacitor) is formed between polysilicon layers 12 and 14 (Poly1 and Poly2). The capacitance of the inter-polysilicon capacitor is determined by the thickness of ONO composite layer 13 and the surface area between ONO composite layer 13 and polysilicon layers 12 and 14. An example of ONO thickness composition is 40/60/40 angstroms respectively.

The primary factor that determines the gate coupling coefficient is the inter-polysilicon capacitance with respect to the tunnel oxide capacitance. The gate coupling coefficient increases as the inter-polysilicon capacitance increases, and as tunnel oxide capacitance decreases. Tunnel oxide capacitance is determined by tunnel oxide thickness which is selected based on a minimum thickness providing maximum read current and yet assuring charge retention characteristics, and can not be independently scaled. An example of tunnel oxide thickness in flash cell is about 90-95 angstroms. The inter-polysilicon capacitance can be increased by increasing the inter-polysilicon capacitor surface area or by reducing the thickness of ONO composite layer 13. However, the thickness of ONO composite layer 13 cannot be reduced much, because the ability of the floating gate to retain charge carriers is reduced as the ONO composite layer thickness is reduced. Typically, in non-volatile technologies such as flash, the thickness of ONO composite layer 13 is reduced to at or near its minimum possible value beyond which charge retention in the floating gate may be compromised.

The gate coupling coefficient can also be increased by increasing the ratio of surface area of the inter-polysilicon capacitor with respect to tunnel oxide surface area. ONO capacitor surface area is determined by the full width of polysilicon layer 12 including cell active width and where polysilicon layer 12 overlaps STI regions 11A-11B, and polysilicon layer 12 sidewalls. Tunnel oxide capacitor surface area is determined by the cell active width. Thus the gate coupling can be increased by increasing Poly1 (layer 12) to isolation overlap. This would require increasing isolation spacing (isolation size) to resolve Poly1-to-Poly1 spacing. However, increasing isolation spacing results in a larger cell size. In fact, the general trend of reducing cell size has resulted in a reduction in the active cell width of flash memory transistors, reduction in isolation spacing and the polysilicon 12 to STI 11A-11B overlap.

The smaller polysilicon 12 to STI 11A-11B overlap reduces the gate coupling coefficient and as a consequence, adversely effects the performance of the memory cell including program and erase efficiency and read speed. Thus, scaling down the size of the memory cell transistors limits the ability to enhance cell performance in conventional technologies.

It would therefore be desirable to provide a cell structure and method for forming the same to enhance the gate coupling coefficient of non-volatile memory transistors that allows the size of the transistors to be reduced without compromising the performance of the memory chip.

### BRIEF SUMMARY OF THE INVENTION

The present invention provides non-volatile memory cell transistors that have increased control-to-floating gate coupling coefficients due to a non-uniform gate surface area. In memory transistors of the present invention, the floating gate is formed with a non-flat, non-uniform surface, which significantly increases the surface area interface between the floating gate and the inter-gate dielectric as well as the surface area interface between the inter-gate dielectric and the control gate. As a result, the inter-gate capacitance and the gate coupling coefficient are significantly increased. A high gate coupling coefficient allows the creation of small sized memory cells that have high program and erase efficiency and read speed. Memory cells of the present invention include flash memory cells, EEPROM cells, and any types of non-volatile memory cell with floating gate.

### BRIEF DESCRIPTION OF THE DRAWINGS

FIGS. 1A-1B illustrate cross section views of prior art stacked-gate non-volatile memory cells along a word line and a bit line, respectively;

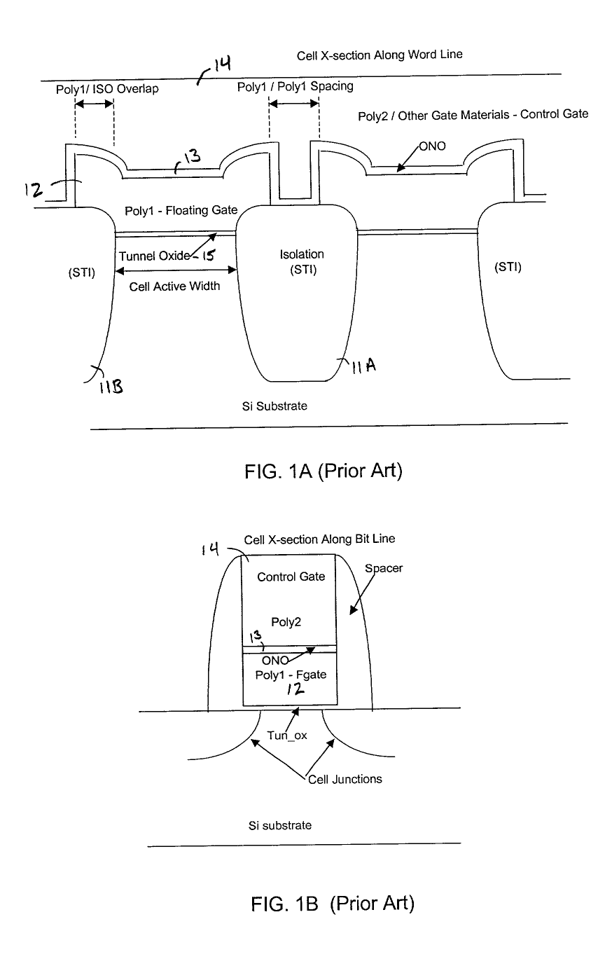

FIGS. 2A-2B illustrate cross section views of stacked-gate non-volatile memory cells along a word line and a bit line, respectively, in accordance with a first embodiment of the present invention;

FIGS. 3A-3B illustrate cross section views of stacked-gate non-volatile memory cells along a word line and a bit line, respectively, in accordance with a second embodiment of the present invention; and

FIG. 4 illustrates a cross section view of a split-gate non-volatile memory cell in accordance with an embodiment of the present invention.

### DETAILED DESCRIPTION OF THE INVENTION

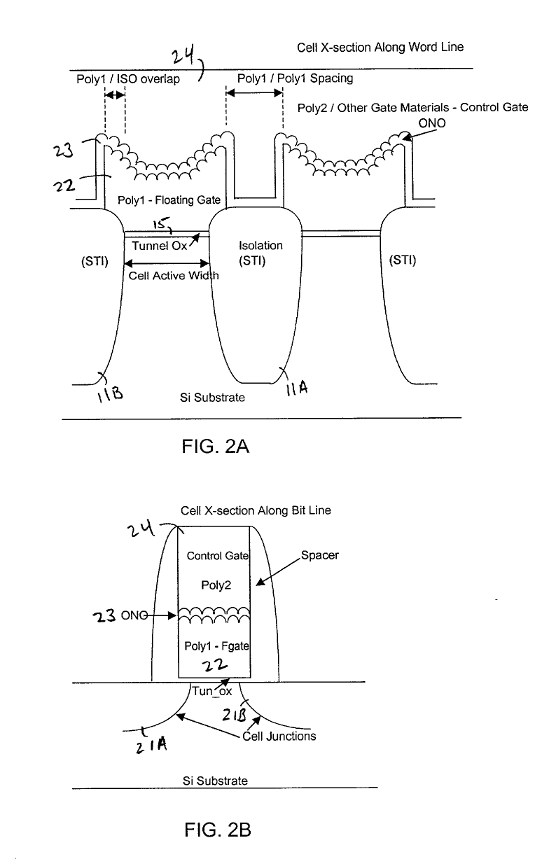

FIGS. 2A-2B illustrate cross section views of stacked-gate non-volatile memory cells along a word line and a bit line, respectively, in accordance with a first embodiment of the present invention. Various types of techniques may be used to isolate the memory cells from each other, such as local oxidation of silicon (LOCOS) or shallow trench isolation (STI). In FIG. 2A, shallow trench isolation regions 11A-11B are used to isolate the cells, although other isolation techniques may also be used. The memory cells are formed in a silicon substrate. A tunnel oxide layer 15 is grown over the silicon substrate.

A first polysilicon layer is deposited over tunnel oxide 15 using, for example, conventional chemical vapor deposition (CVD). Then, in a first embodiment of the present invention, an additional deposition of polysilicon forming a non-flat, non-uniform surface, e.g. hemispherical grained deposition of polysilicon, is performed followed by patterning of the polysilicon layer to form floating gates 22 with non-uniform surfaces as shown in FIGS. 2A and 2B. Further details of hemispherical grained deposition are discussed in M. Sakao, et al., “A Capacitor-Over-Bit-Line (COB) Cell with a Hemispherical-Grain Storage Node for 64 Mb DRAMs,” IEDM, p 655-658, 1990, which is incorporated by reference herein.

In a second embodiment of the present invention, conventional CVD of the first layer polysilicon is followed by a processing step designed to modify the morphology and topography of the deposited polysilicon layer to form a non-flat, non-uniform surface, e.g. using the seed method. The seed method involves irradiating the surface of the deposited polysilicon layer with Si₂H₆ gas to create amorphous silicon seeds over the surface of the polysilicon layer, and then annealing the wafer under certain conditions at a high temperature (e.g., 580° C.). Further details of the seed method are discussed in H. Watanabe, et al. “Hemispherical Grained Silicon (HSG-Si) Formation on In-Situ Phosphorous Doped Amorphous-Si Using the Seed Method,” SSDM, p. 422-424, 1992, which is incorporated herein by reference. Other methods of forming a non-flat or a non-uniform polysilicon layer surface can also be used to achieve the advantages of the present invention.

In both embodiments, floating-gate 22 has a large surface area due to its non-flat, non-uniform (e.g., hemispherical grained) surface as shown in FIGS. 2A-2B. In this embodiment, the sidewalls of floating-gate 22 (above STI regions 11A-11B) are relatively flat, but the upper surfaces of floating gates 22 retain the hemispherical grained shape as shown in FIG. 2A. Performing the polysilicon patterning step after the formation of the hemispherical grained polysilicon surface of floating-gate 22 flattens the sidewalls of floating-gate 22.

Subsequently, an inter-polysilicon dielectric 23 is formed on top of floating-gate 22. Inter-polysilicon dielectric 23 typically is an oxide-nitride-oxide (ONO) composite layer or sometimes an oxide-nitride-oxide-nitride (ONON) composite layer. Portions of dielectric 23 may be removed from peripheral regions of the device. As dielectric 23 is deposited, it forms in a non-flat, non-uniform, e.g. hemispherical grained, pattern contoured to the non-uniform, e.g. hemispherical, upper surface of floating-gate 22 as shown in FIGS. 2A-2B. The surface area of the interface between floating-gate 22 and dielectric 23 is greatly increased, because of the non-uniform hemispherical pattern of the interface.

Then, a second polysilicon gate layer 24 is deposited on top of interpolysilicon dielectric 23. Other layers such as tungsten silicide (WSi_{X}), or cobalt silicide, etc. may be formed on gate layer 24. Because gate layer 24 is deposited on top of the non-uniform, e.g. hemispherical, upper surface of inter-polysilicon dielectric 23, the layer 24 to dielectric 23 interface is also non-uniform as shown in FIGS. 2A-2B, providing a larger surface area at the interface of dielectric 23 and gate layer 24.

A gate mask and gate etch are then performed to define the control gate of the memory array cells. The gate stacks of the memory array cells may be formed using a self-aligned etch process. Polysilicon layer 24 forms the control gates for the memory cells. The gates of peripheral transistors may be formed simultaneously with the control gate of the memory array cells. Other steps are then performed to complete the formation of the memory cell and peripheral transistors according to well-known techniques. For example, dopants are implanted into the substrate after formation of the gate layers to form drain and source regions 21A and 21B shown in FIG. 2B.

The increased inter-polysilicon capacitor surface area provided by the non-uniform interfaces between floating-gate 22 and inter-polysilicon dielectric 23 as well as between gate layer 24 and inter-polysilicon dielectric 23 greatly increases the interpolysilicon capacitance, which significantly increases the control gate-to-floating gate coupling coefficient. The significantly higher control gate-to-floating gate coupling coefficient achieved by the non-flat, non-uniform, three-dimensional, rounded, repeatable interface between the two polysilicon layers and the inter-polysilicon dielectric allows the size of the memory cell to be substantially reduced without compromising cell program/erase efficiency and read speed.

The present invention has broad applicability in the floating-gate non-volatile memory technology area, and is not limited to any particular process steps. The non-flat, non-uniform floating gate and control gate (typically made of polysilicon) interfaces with repeatable grain patterns can be applied to numerous types of non-volatile memory cell structures and process steps as well as methods of integrating memory array and peripheral transistors (e.g., EPROM, EEPROM, and flash technologies), and in general any types of non-volatile memory cell with floating gate.

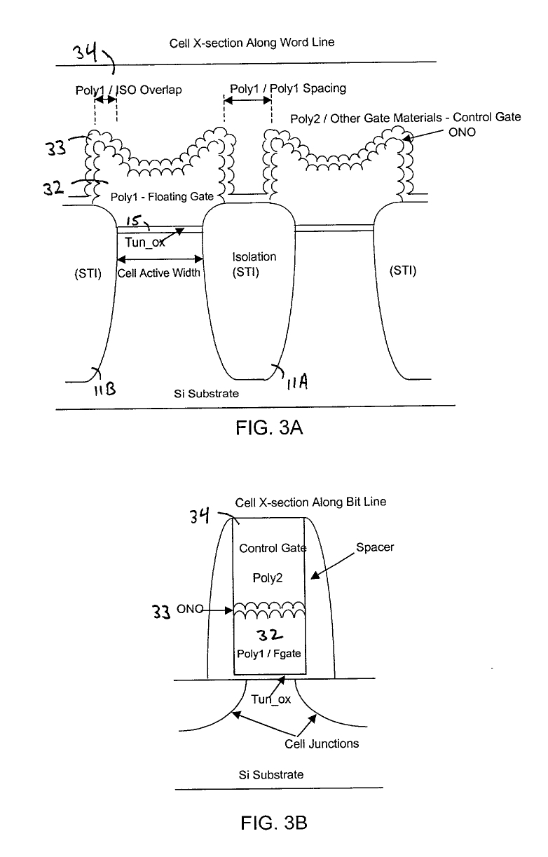

FIGS. 3A-3B illustrate cross section views of stacked-gate non-volatile memory cells along a word line and a bit line, respectively, in accordance with a second embodiment of the present invention. In this embodiment, first polysilicon layer is formed using conventional CVD deposition. Then, the deposited polysilicon is patterned (e.g., etched) to form floating gates 32 for the memory array cells. Subsequently, a polysilicon layer with non-flat, non-uniform surface, e.g. hemispherical grained polysilicon, is deposited on floating-gate 32 (as discussed above) followed by an etch back step to remove residual polysilicon above the STI regions 11A-11B. The deposition and etching steps are done in such a way as to retain the non-uniform, e.g. hemispherical grained, surface of floating-gate 32.

In another embodiment, after the first polysilicon layer is deposited and patterned a selective deposition or selective epitaxial growth of another layer of polysilicon with non-uniform grained surface is performed. The selective deposition takes place only where the previous layer of polysilicon is present, and will not require a etch back step since there will be no residual polysilicon above isolation regions (e.g., STI or LOCOS). In a further embodiment, the morphology and topology of floating-gate 32 is modified using, for example, the seed method described above. In either case, the non-uniform, e.g. hemispherical, shape of floating-gate 32 is retained along its upper surface and sidewalls as shown in FIG. 3A.

Subsequently, an inter-polysilicon dielectric 33 (such as ONO) is deposited on top of floating-gate 32 and removed from peripheral regions. Dielectric 33 forms a non-uniform, e.g. hemispherical, pattern as it is deposited on top of the non-uniform surface of floating-gate 32, because dielectric 33 contours to the non-uniform surface of floating-gate 32. A second polysilicon gate layer 34 is then deposited on top of interpolysilicon dielectric 33. Gate layer 34 contours to the non-uniform, e.g. hemispherical, pattern of dielectric 33 as it is deposited thereon, creating a non-uniform gate layer 34 to inter-polysilicon dielectric 33 interface as shown in FIGS. 3A-3B.

Subsequently, further dielectric layers may be formed on gate layer 34.

Gate mask and etch steps are then performed to form the control gate for the memory array cells. Gate layer 34 forms the control gates for the non-volatile memory cells. Gates for the peripheral transistors may also be formed during the gate mask and etch steps. Further well-known process steps are then performed to complete the formation of the cells and peripheral transistors.

The non-uniform, e.g. hemispherical, interface between floating-gate 32 and dielectric 33 and between dielectric 33 and gate layer 34 greatly increases the surface area of the inter-polysilicon capacitor around the upper and sidewall surfaces of floating-gate 32. Thus, the embodiment of FIGS. 3A-3B provides a greater gate coupling coefficient for a given cell size, achieving better memory cell performance as discussed above. Accordingly, the size of memory cells can be reduced without compromising device performance requirements. A high gate coupling coefficient allows the creation of small sized high performance memory cells that have high program and erase efficiency and read speed and can function at lower operation voltages. Higher gate coupling ratio allows also lowering operation voltages of memory cells which simplifies flash chip design, especially for lower power supply voltages.

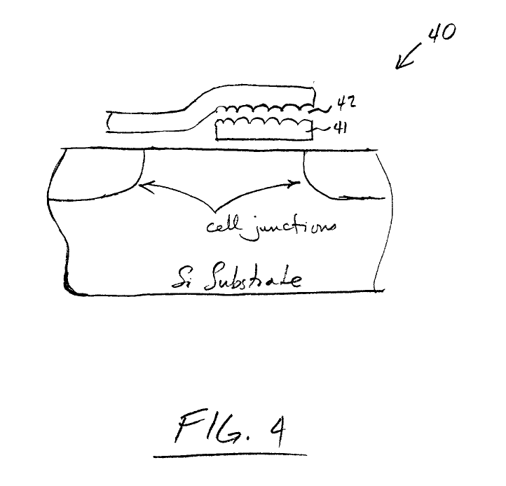

As indicated earlier, the present invention has broad applicability in the non-volatile memory technology area, and may be applied to any cell technology which includes a floating gate. For example, FIG. 4 shows a cross section view of a double-polysilicon split-gate non-volatile memory cell 40, wherein floating-gate 41 and interpolysilicon dielectric 42 are formed in accordance with the present invention. Other floating-gate cell structures, such as triple-polysilicon flash cell and EEPROM cells can be similarly modified by one skilled in the art to realize the features and advantages of the present invention.

Although, in the above embodiments, the inter-polysilicon capacitance is the primary focus, one skilled in the art would be able to apply the teachings of the present invention to any other areas of non-volatile memory cells wherein a larger effective capacitance is desired.

While the present invention has been described herein with reference to particular embodiments thereof, a latitude of modification, various changes and substitutions are intended in the foregoing disclosure, and it will be appreciated that in some instances some features of the invention will be employed without a corresponding use of other features without departing from the scope of the invention as set forth. Therefore, many modifications may be made to adapt a particular situation or material to the teachings of the invention without departing from the essential scope and spirit of the present invention. It is intended that the invention not be limited to the particular embodiments disclosed, but that the invention will include all embodiments and equivalents falling within the scope of the claims. A multitude of processing techniques can be used to create non-flat, non-uniform floating and control gate interfaces to increase the respective inter-gate capacitance.

What is claimed is:

1. A method for forming a non-volatile memory cell, the method comprising:
forming a floating-gate having at least one non-uniform surface over, but insulated from, a semiconductor region;
forming a dielectric on the non-uniform surface of the floating-gate such that the dielectric comprises a non-uniform surface;
forming a control gate layer over the non-uniform surface of the dielectric so that an interface between the control gate layer and the dielectric is non-uniform; and
patterning the control gate layer to form a control gate.

2. The method of claim 1 wherein floating gate comprises polysilicon.

3. The method of claim 1 wherein the control gate layer comprises polysilicon.

4. The method of claim 1 wherein the non-uniform surface of the floating-gate is a hemispherical grained surface.

5. The method of claim 1 wherein the non-uniform surface of the dielectric is a hemispherical grained surface contoured with the hemispherical grained surface of the floating-gate.

6. The method of claim 1 wherein the non-uniform surface of the floating-gate is formed by irradiating the surface of the floating-gate with Si₂H₆ gas to create amorphous silicon seeds over the surface of the floating-gate and then annealing the floating-gate layer.

7. The method of claim 1 wherein forming the floating-gate further comprises:
forming a first layer of polysilicon; and
depositing grains of polysilicon over the first layer of polysilicon to form said non-uniform surface.

8. The method of claim 7 further comprising patterning the first polysilicon gate layer to form the floating-gate after said depositing grains of polysilicon.

9. The method of claim 7 further comprising patterning the first polysilicon layer to form the floating-gate before said depositing grains of polysilicon such that the floating-gate has a non-uniform surface along its upper and sidewall surfaces.

10. The method of claim 9 further comprising removing the deposited grains of polysilicon from over a portion of an isolation region isolating the cell from other neighboring cells.

11. The method of claim 7 further comprising patterning the first polysilicon layer to form the floating-gate followed by selective deposition of non-uniform grained polysilicon on the first polysilicon layer such that the floating-gate has a non-uniform surface along its upper and sidewall surfaces.

12. The method of claim 7 further comprising patterning the first polysilicon layer to form the floating-gate followed by selective epitaxial growth of non-uniform grained polysilicon on the first polysilicon layer such that the floating-gate has a non-uniform surface along its upper and sidewall surfaces.

13. The method of claim 12 where non-uniform grained polysilicon is hemispherical grained polysilicon.

14. The method of claim 1 wherein the dielectric comprises an oxide-nitride-oxide composite layer.

15. The method of claim 1 wherein the dielectric comprises an oxide-nitride-oxide-nitride composite layer.

16. A non-volatile memory cell comprising:
a floating-gate over, but insulated from, a semiconductor region, the floating-gate having an upper surface that is substantially non-uniform;
a dielectric formed on the non-uniform surface of the floating-gate, the dielectric comprising a non-uniform surface that is contoured according to the non-uniform surface of the floating-gate; and
a control gate formed on the non-uniform surface of the dielectric, the control gate comprising a non-uniform surface that is contoured according to the non-uniform surface of the dielectric.

17. The memory device of claim 16 wherein the floating gate and the control gate comprise polysilicon.

18. The memory device of claim 16 wherein the dielectric comprises an oxide-nitride-oxide composite layer.

19. The memory device of claim 16 wherein the dielectric comprises an oxide-nitride-oxide-nitride composite layer.

20. The memory device of claim 16 wherein the non-uniform upper surface of the floating-gate is a hemispherical grained surface.

21. The memory device of claim 20 wherein the non-uniform surface of the dielectric is a hemispherical surface contoured according to the hemispherical grained surface of the floating-gate.

22. The memory device of claim 20 wherein the non-uniform lower surface of the control gate is a hemispherical surface contoured according to the hemispherical surface of the dielectric.

23. The memory device of claim 16 wherein the non-uniform upper surface of the floating-gate is formed by irradiating the surface of the floating-gate with Si₂H₆ gas to create amorphous silicon seeds over the surface of the floating-gate and then annealing the floating-gate.

24. The memory device of claim 16 wherein the non-uniform upper surface of the floating-gate is formed by depositing hemispherical grains of polysilicon over a first polysilicon layer.

25. The memory device of claim 24 wherein the first polysilicon layer is patterned to form the floating-gate before depositing the hemispherical grains of polysilicon.

26. The memory device of claim 24 wherein the first polysilicon layer is patterned to form the floating-gate after depositing the hemispherical grains of polysilicon.

27. The memory device of claim 16 wherein the memory cell is one of an EPROM, an EEPROM, and a flash cells.

28. A semiconductor memory cell comprising:
a drain region and a source region forming a channel region there between;
a floating-gate extending over, but insulated from, the channel region, the floating-gate having at least one substantially non-uniform surface; and
a control gate over but insulated from the floating-gate,
wherein the memory cell is a non-volatile memory cell.

29. The memory cell of claim 28 wherein the non-uniform surface of the floating-gate is a surface of the floating-gate closest to the control gate.

30. The memory cell of claim 28 wherein the floating gate and at least one of the layers that make up the control gate comprise polysilicon.

31. The memory cell of claim 28 wherein the floating-gate comprises:
a first layer polysilicon, and
a hemispherical grain of polysilicon.

32. The memory cell of claim 31 wherein the floating-gate is insulated from the control gate by a dielectric, the dielectric having a non-uniform surface at each of the dielectric to floating-gate interface and dielectric to control gate interface.

33. The memory cell of claim 28 wherein the control gate layer on top of the dielectric is made of polysilicon.

34. The memory cell of claim 28 wherein the floating-gate has a non-uniform surface at each of its upper and side-wall surfaces.

35. The memory cell of claim 28 further comprising isolation regions configured to isolate the memory cell from adjacent memory cells, wherein the floating-gate overlaps the isolation region.

36. The memory cell of claim 28 further comprising isolation regions configured to isolate the memory cell from adjacent memory cell structures, wherein the floating-gate does not overlap the isolation region.
